(19) United States
(12) Patent Application Publication
(10) Pub. No.: US 2025/0311133 A1
(43) Pub. Date: Oct. 2, 2025

(54) MECHANICAL STACK ASSEMBLY WITH RELEASABLE COMPRESSION

(71) Applicant: Intel Corporation, Santa Clara, CA (US)

(72) Inventors: Smit Kapila, Bangalore (IN); Min Suet Lim, Gelugor (MY); Jeff Ku, Taipei City (TW); Arturo Navarro Alvarez, San Isidro (CR); Surya Pratap Mishra, Portland, OR (US); Shantanu D. Kulkarni, Hillsboro, OR (US); Kari Pekka Johannes Mansukoski, Hillsboro, OR (US)

(73) Assignee: Intel Corporation, Santa Clara, CA (US)

(21) Appl. No.: 18/622,711

(22) Filed: Mar. 29, 2024

(51) Int. Cl. H05K 7/12

(52) U.S. Cl. CPC H05K 7/12

(57) ABSTRACT

An apparatus provides a cover and a compression mechanism coupled to the cover. The compression mechanism includes an anchor extending through the cover, a lever disposed in a first plane traversing the cover, and a contact portion disposed in a second plane opposing the cover. The lever and the contact portion are in a biased relationship about a common axis. When a rotational force is applied to the lever, a rotational movement of the lever causes the contact portion to be compressed against the cover and allows the lever to be releasably restrained by the first anchor. The compression mechanism may further include two biasing elements coupled to opposite ends of the lever. The two biasing elements are aligned along the common axis. The anchor may include an indent sized to receive a section of the lever.

### BACKGROUND

Mechanical stack assemblies are structures used to stack electronic components to form a compact and integrated electronic system. Various layers may be used in these assemblies including motherboards, printed circuit boards, heat spreaders, and substrates, for example. Screws or similar hardware is often used to secure the layers. In certain mechanical stack assemblies, components of the assembly may need to be repaired or replaced. Also, more uniform heat distribution over some components is desirable.

### BRIEF DESCRIPTION OF THE DRAWINGS

FIG. 1 is an exploded view of an example mechanical stack assembly with a compression mechanism according to the present disclosure.

FIG. 2 is a cutaway top, front, and side perspective view of the mechanical stack assembly of FIG. 1 in an assembled arrangement.

FIG. 3 is a cutaway top, front, and side perspective view of the assembled mechanical stack assembly of FIG. 2 in which a cover is omitted.

FIG. 4 is cross-sectional view of the assembled mechanical stack assembly of FIG. 2 and including a substrate.

FIG. 5 is another cross-sectional view of the assembled mechanical stack assembly of FIG. 2.

FIG. 6 is a cutaway top, front, and side perspective view of the assembled mechanical stack assembly of FIG. 2 with levers of the compression mechanism in a fixed position.

FIGS. 7A-7B are side views of possible angles for levers of the compression mechanism in a free position.

FIGS. 8A-8D are diagrams illustrating results of a structural analysis of a simulated elongated spring of an example compression mechanism.

FIG. 9 is a cutaway top, front, and side perspective view of an assembled mechanical stack assembly with an alternative embodiment of a compression mechanism with levers shown in a fixed position.

FIG. 10 is a cutaway perspective view showing more details of an intermediate lever member of an elongated spring in the compression mechanism of FIG. 9.

FIG. 11 is a cross-sectional view of the assembled mechanical stack assembly of FIG. 9.

FIG. 12 is another cross-sectional view of the assembled mechanical stack assembly of FIG. 9, showing levers of the compression mechanism in a free position.

FIG. 13 is yet another cross-sectional view of the assembled mechanical stack assembly of FIG. 9.

FIGS. 14A-14D depict alternative example compression mechanisms that may be implemented in examples disclosed herein.

FIG. 15 is a flow diagram of a possible example process associated with producing a mechanical stack assembly with a compression mechanism.

### DETAILED DESCRIPTION

The present disclosure provides various possible embodiments, or examples, of systems, methods, apparatuses, architectures for a compression mechanism used in a mechanical stack assembly. In particular, embodiments disclosed herein provide for a screwless assembly mechanism in which an elongated spring is designed to provide releasable compression over selected components in a mechanical stack. The releasability feature enables simplified access to components on which compression is applied by the elongated spring. In addition, the compression provided may be designed for particular measurements over particular components. Furthermore, the compression mechanism can apply substantially uniform compression over multiple selected components in the mechanical stack.

For some electronic components in a mechanical stack assembly, repair or replacement requires disassembly of the mechanical stack. When multiple screws or similar hardware is used, access to the components can be time-consuming and challenging. Thus, the use of mechanical screws in mechanical stack assemblies can detrimentally impact serviceability as a user may need additional tools, such as a screwdriver, to service the assembly. Using multiple mechanical screws also increases the likelihood of loose parts in the assembly.

In one example, Low Power Compression Attached Memory Module (LPCAMM) components are detachable modules offering increased memory bandwidth and modularity. Such characteristics are in high demand for modern computers such as artificial intelligence (AI) computers. Compared to user-friendly plug-and-remove options, such as small outline dual inline memory module (SoDIMM) components, LPCAMM components have a lower “repairability score” when used in mechanical stack assemblies that rely on screws to fasten and compress the layers.

Heat spreaders are often used in mechanical stack assemblies to prevent overheating and improve processing of memory modules, such as LPCAMM, or other heat-sensitive components. A heat spreader is usually compressed against the memory modules to provide a heat conductive path to enable component cooling. Structural hardware (e.g., screws, braces) is typically screwed into the layers of the assembly to compress the heat spreader. The force applied by screws or other structural hardware may be applied to the assembly in an uneven manner. Thus, the heat conductive path of the spreader could be compromised, resulting in inadequate cooling.

Additionally, if not properly applied, a screw torque could negatively impact the component functionality. Furthermore, the use of multiple screws increases the likelihood of improper compression being applied to at least one component. Uneven pressure distribution across LPCAMM components can cause imbalanced pressure to both edges of the module, which can lead to open/higher impedance signal path. Thus, a more simplified assembly mechanism that applies a more uniform compressive force on components is needed.

A compression mechanism for mechanical stack assemblies, as disclosed herein can resolve many of the aforementioned issues (and more). In one or more embodiments, an elongated spring is used to releasably fasten the layers of a mechanical stack assembly for an electronic system and apply a selected amount of compressive force across one or more components. The elongated spring can be assembled across a cover (e.g., shield, top plate, spreader, heat gasket, etc.). The elongated spring can include one or more levers that, when a torque is applied, can be releasably restrained in a fixed position by a corresponding one or more anchors coupled to a base of the assembly. In one example, the anchors include hook-like indents, rather than threads. Respective sections of the one or more levers are inserted into the hook-like indents, respectively, and releasably coupled thereto. The anchors may extend through through-holes of one or more layers including the cover and the layer with components across which pressure is to be distributed (e.g., memory module such as LPCAMM).

The spring also includes one or more contact portions that are vertically aligned with the components that are to receive the compressive force and that are biased against (or apply a compressive force to) the cover when the levers are restrained in the fixed position. In an example, the one or more levers and contact portions are designed as a torsional spring with multiple biasing elements. A biasing element may be formed as a bend (e.g., a turn, a coil, etc.) in the spring that biases an arm of a lever and another arm (e.g., a contact arm, an outer arm, etc.). In one example, biasing elements are formed at the ends of the arms of the levers and the multiple biasing elements are aligned along a common axis.

The compression mechanism for mechanical stack assemblies, as disclosed herein, offers several advantages. First, a mechanical stack assembly can be assembled without screws or other structural hardware with threads when a releasable compression mechanism, as described herein, is used instead. Using a single elongated spring with anchors limits the number of loose parts as compared to a mechanical stack assembly put together with multiple screws. Thus, serviceability may be improved. Furthermore, restraining one or more levers of a single elongated spring can reduce operational time during factory assembly. A single move (e.g., 2-3 seconds) can be used to restrain all of the levers, rather than tightening three or more screws (e.g., 10 or more seconds). Furthermore, utilizing the compression mechanism disclosed herein for a memory module (e.g., LPCAMM) assembly could achieve an assembly time that is 4-5 times faster than an existing screw-based assembly.

The compression mechanism taught herein allows for an appropriate and more uniform compression force to be applied to the layers in the mechanical stack assembly. The additional compression force of an elongated spring (e.g., 82 pounds), as described herein, relative to existing screws (e.g., 45 pounds) ensures that a minimum load is applied to every pin of components aligned with a contact portion of the spring. Additionally, the load can be applied over each component (e.g., memory modules), rather than on the printed circuit board. The elongated spring itself can be designed to achieve any selected number of pressure points based, for example, on the number of components (e.g., LPCAMM components) to be compressed.

A compression mechanism having a releasability feature as disclosed herein may be more consistent and reliable than screws and other threaded structural hardware. For example, if the appropriate screw torque is not applied, the functionality of a component receiving the compressive force may be negatively impacted.

The various possible designs of a compression mechanism taught herein do not increase the size of a typical mechanical assembly. Because existing mechanical stack assemblies can be modified to use a compression mechanism as disclosed herein with minimal or no height, width, and depth increases, the chassis of such existing assemblies would not be impacted. Accordingly, the compression mechanism disclosed herein can achieve the same or substantially the same Z-height of existing screw-based solutions.

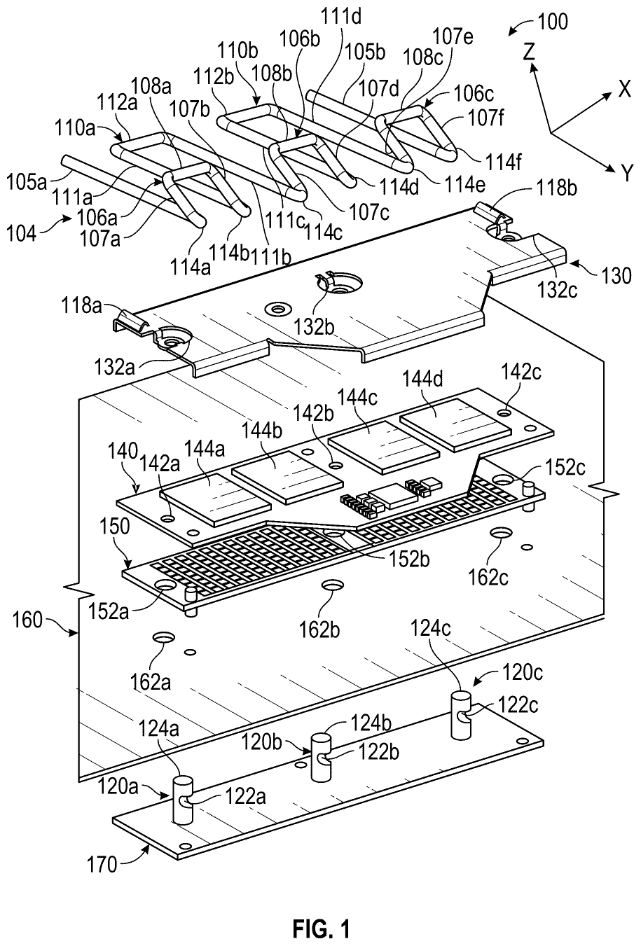

Reference is now made to the drawings. FIG. 1 is an exploded view of an example mechanical stack assembly 100 with a compression mechanism 102 according to one example. The mechanical stack assembly 100 further includes a cover 130 with through-holes 132a, 132b, and 132c, a memory module 140 with through-holes 142a, 142b, 142c, a compressive connector 150 with through-holes 152a, 152b, 152c, a motherboard 160 with through-holes 162a, 162b, 162c, and a base 170 with anchors 120a, 120b, 120c. The cover 130 is vertically spaced from the base 170 with the other layers disposed therebetween.

The compression mechanism 102 includes an elongated spring 104 and anchors 120a, 120b, and 120c (collectively referenced as 120). Elongated spring 104 can be configured as any suitable biased structure such as a torsional spring, double torsional spring, triple torsional spring, etc., rotatable crank, rods, shafts, etc. Elongated spring 104 can be made of any suitable material that can be configured into a biased structure that is rotatable from an original (e.g., at rest or free) position to a particular angular deflection in response to a torque, and that returns to the original position once the torque is removed. Example materials include, but are not limited to, spring steel, such as stainless steel, music wire, chrome silicon, hard drawn, or oil tempered, copper-based alloys, nickel-based alloys, aluminum, or suitable combinations thereof, for example.

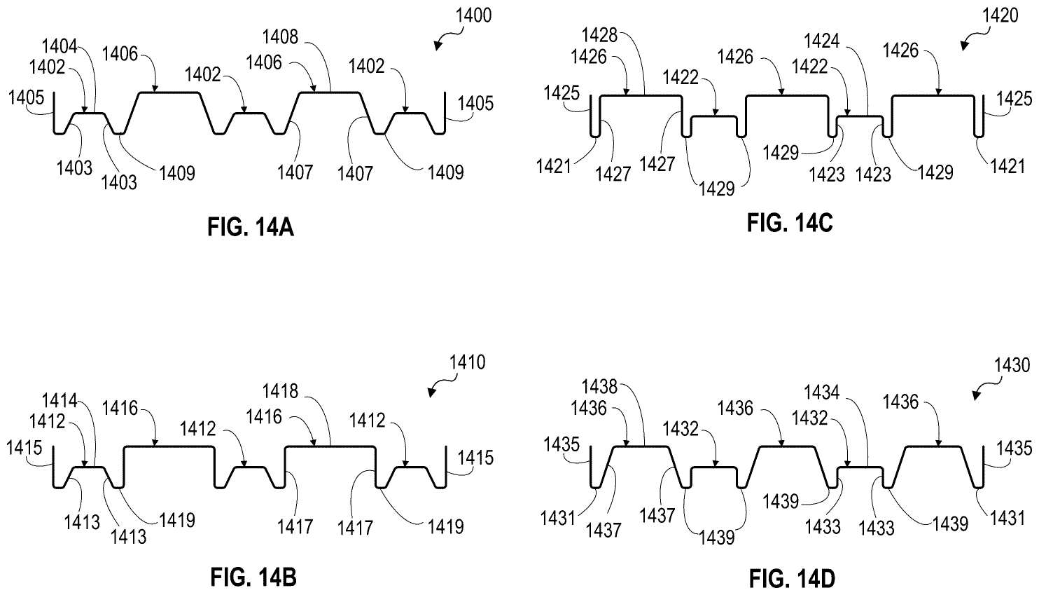

The example elongated spring 104 in FIG. 1 includes three levers 106a, 106b, and 106c (collectively referenced as 106), and two contact portions 110a and 110b, although the number of levers and contact portions, and the placement thereof within the elongated spring 104, may vary depending on the particular configuration of the mechanical stack assembly and components upon which a compressive force is to be applied. Generally, the levers 106 may be configured with respective pairs of lever arms 107a-107b, 107c-107d, and 107e-107f (collectively referenced as 107), and with respective intermediate lever members 108a, 108b, and 108c (collectively referenced as 108). The intermediate lever members 108 connect respective pairs of lever arms 107a-107b, 107c-107d, 107e-107f to form 3-sided, generally rectangular levers 106. In other examples, however, levers 106 can be any suitable shape including, but not limited to, U-shapes, curved shapes, spline shapes, ellipsoid shapes, trapezoidal shapes, etc., as will be further described herein with reference to FIGS. 14A-14D.

The contact portions 110a, 110b (collectively referenced as 110) may be configured with respective pairs of contact arms 111a-111b, 111c-111d (collectively referenced as 111), and with respective intermediate contact members 112a, 112b (collectively referenced as 112). The intermediate contact members 112 connect respective pairs of contact arms 111a-111b, 111c-111d to form 3-sided, generally rectangular contact portions 110. In other examples, however, the contact portions 110 can be any suitable shape including, but not limited to, U-shapes, curved shapes, spline shapes, ellipsoid shapes, trapezoidal shapes, etc., as will be further described herein with reference to FIGS. 14A-14D.

A biasing element 114a, 114b, 114c, 114d, 114e, or 114f (collectively referenced as 114) is provided at the end of each of the lever arms 107. In one example, the biasing elements 114 form a torsional spring (or any other suitable spring type) where each biasing element is shaped as a single bend or turn of a rod (e.g., bar, shaft, wire, etc.) that works (e.g., responds to rotational movement of a lever arm by twisting, turning, etc.) in a clockwise or counterclockwise direction. One end of a given biasing element (e.g., 114a) extends into a lever arm (e.g., 107a) and an opposite end of the biasing element extends into another arm biased against the lever arm. Thus, each end of a lever 106 is in a biased relationship with another arm. As shown in FIG. 1, the other arm is either a contact arm of an adjacent contact portion or an outer arm that is used to couple the elongated spring 104 to the cover 130. In other examples, the other arm may be a connecting arm (not shown) to another lever, or a connecting arm to a contact portion.

In an example, the biasing elements 114 are aligned along a common axis about which the levers can be rotated to a certain angular deflection. A first biasing element 114a connects and biases a first outer arm 105a to lever arm 107a of the first lever 106a such that the first biasing element 114a works in a first direction (e.g., clockwise). A second biasing element 114b connects and biases the lever arm 107b of the first lever 106a to the contact arm 111a of the first contact portion 110a such that the second biasing element 114b works in the first direction (e.g., clockwise). A third biasing element 114c connects and biases the lever arm 107c of the second lever 106b to the contact arm 111b of the first contact portion 110a such that the third biasing element 114c works in a second direction (e.g., counterclockwise). A fourth biasing element 114d connects and biases the lever arm 107d of the second lever 106b to the contact arm 111c of the second contact portion 110b such that the fourth biasing element 114d works in the first direction (e.g., clockwise). A fifth biasing element 114e connects and biases the lever arm 107e of the third lever 106c to the contact arm 111d of the second contact portion 110b such that the fifth biasing element 114e works in the second direction (e.g., counterclockwise). A sixth biasing element 114f connects and biases the lever arm 107f of the third lever 106c to a second outer arm 105b such that the sixth biasing element 114f works in the second direction (e.g., counterclockwise). In other embodiments, the work (e.g., twist) direction of the biasing elements 114 may be only clockwise, only counterclockwise, or any combination thereof.

The elongated spring 104 can be assembled on cover 130. The cover 130 may be a shield, a heat spreader, a lid, a plate, or any other suitable structure that is to be compressed onto a printed circuit board (PCB) including integrated circuit components, such as memory module 140 including memory components (e.g., LPCAMM, etc.), or onto another suitable layer of a mechanical stack assembly. In an example, cover 130 provides a conductive heat path to allow cooling of a PCB layer below the cover.

The elongated spring 104 is secured, positioned, and/or aligned on an outer surface 134 of cover 130 with retainers (e.g., securing mechanisms, fasteners, clips, lugs, clamps, openings, indents, cavities, etc.) that are coupled to and/or defined by the structure (e.g., molded, stamped, cast, bent, assembled, etc.) of the cover. Alternatively or additionally, retainers 118a-118b (collectively referenced as 118) may be rigidly coupled to the cover 130 (e.g., by solder, welding, screws, rivets, etc.). In FIG. 1, retainers 118 are shaped as arched housing structures that are secured (e.g., mechanically attached, chemically bonded, mechanically bonded, etc.) to opposite sides of the outer surface 134 of cover 130, or formed as the structure (e.g., stamped, cast, bent, etc.) of the cover 130. Each retainer 118a, 118b defines an opening therein sized to slidably receive a distal portion of a corresponding outer arm 105a, 105b (collectively referenced as 105). The retainers could, alternatively, be U-clamps, U-bracket, U-strap, pipe clamp, pipe strap, pipe strap, tube strap, etc. or any other device or structure sized to receive a distal portion of a corresponding outer arm.

The compression mechanism 102 also includes anchors 120a, 120b, and 120c (collectively referenced as 120) to releasably restrain (e.g., lock, hold, constrain, retain, etc.) levers 106, respectively, in a fixed position. In an example, anchors 120 extend from respective lower ends at the base 170 (e.g., plate, base plate, back plate, bottom, bottom cover, etc.) through the cover 130 to respective upper ends 124a, 124b, 124c (collectively referenced as 124) that are vertically spaced (e.g., Z-axis) above the outer surface 134 of the cover 130. In one example, anchors 120 may be formed as vertical shafts (e.g., rods, cylinders, standoffs, etc.) coupled to and/or defined by the structure (e.g., stamped, bent, extruded, etc.) of base 170. Each anchor 120a, 120b, and 120c includes a respective upper portion with an indent (e.g., notch, opening, aperture, hook-like cavity, etc.) 122a, 122b, 122c, sized to receive an interlocking section of an adjacent intermediate lever member 108a, 108b, 108c of levers 106, to couple the levers 106 to the anchors 120 such that the elongated spring is loaded (e.g., prevented from rotating) and the levers 106 are restrained in a fixed position until an appropriate releasing force is applied to the levers 106.

Anchor indents 122 are located in respective upper portions that terminate at upper ends 124 of the anchors. In the example of FIG. 1, the indents 122 and adjacent upper ends 124 are disposed above and the outer surface 134 of cover 130. In an example, the indents 122 of the anchors 120 extend sufficiently above the outer surface 134 to receive respective interlocking sections of the levers 106 to couple the levers 106 to the anchors 120 and restrain the levers 106 in a fixed position. When the levers 106 are restrained in a fixed position by the anchors 120, biasing elements 114 are loaded, which causes a compressive force to be applied to the cover 130 by contact portions 110.

In an example, anchors 120 are vertically aligned with respective through-holes of various layers in the mechanical stack. When assembled, the anchors extend through the through-holes such that the upper ends 124 are exposed through the outer surface 134 of the cover 130, and the layers of the mechanical stack are maintained in proper alignment within the mechanical stack. For example, in FIG. 1, anchor 120a extends through through-holes 162a, 152a, 142a, and 132a of the motherboard 160, the compressive connector 150, the memory module 140, and the cover 130, respectively. Anchor 120b extends through through-holes 162b, 152b, 142b, and 132b of the motherboard 160, the compressive connector 150, the memory module 140, and the cover 130, respectively. Anchor 120c extends through through-holes 162c, 152c, 142c, and 132c of the motherboard 160, the compressive connector 150, the memory module 140, and the cover 130, respectively.

In some examples, existing mechanical stack assemblies using other hardware, such as screws, may be easily modified to receive the anchors 120 through the existing through-holes in the various layers of the stack. In other examples, the through-holes may be selectively placed to further minimize or avoid any lateral size increase in the layers of the mechanical stack assembly 100. In further examples, one or more anchors 120 may not extend through every layer, or may not extend through any layer, or may extend only through the cover. For example, one or more anchors 120 may be disposed around the periphery of one or more layers. In yet further examples, one or more anchors 120 may extend from lower ends located at a layer other than the cover 130 to upper ends 124 through or on the periphery of the cover 130 or other layer on which the elongated spring 104 is disposed.

Another layer of a mechanical stack assembly is a PCB, such as memory module 140, which includes one or more components to which compression is applied via the cover 130. In this example, four memory components 144a, 144b, 144c, and 144d (e.g., LPCAMM) (collectively referenced as 144) are included on the PCB. In an example, each contact arm of the contact portions 110 is vertically aligned with one of the memory components 144 to provide a more even or uniform pressure when the compression mechanism 102 is engaged (e.g., levers 106 are restrained in a fixed position, biasing elements 114 are loaded). In other examples, the compression mechanism 102 can be utilized in other mechanical stack assemblies to compress (e.g., via cover 130 or another suitable compressible layer) different types of electronic components and/or electronic circuitry (e.g., dies and/or die packages), for example.

Other layers in mechanical stack assembly 100 include, for example, the compressive connector 150 and motherboard 160. The compressive connector 150 may be designed to create a secure and reliable electrical connection between different layers (e.g., memory module 140 and motherboard 160). The motherboard 160 is a central PCB for a computing system and can include processing units (e.g., central processing unit, graphics processing unit, etc.), random access memory (RAM), storage devices, expansion cards, network interfacing devices, etc. For simplicity, motherboard 160 is not illustrated with components in FIG. 1.

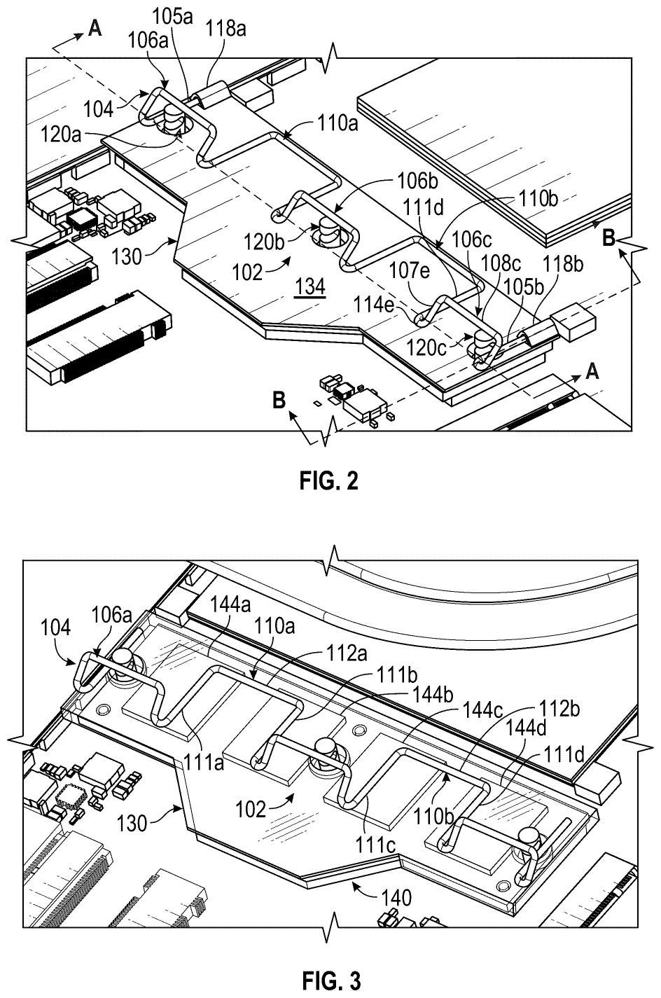

FIG. 2 is a cutaway top, front, and side perspective view of the mechanical stack assembly 100 in an assembled arrangement with levers of the compression mechanism released from corresponding anchors. In FIG. 2, the elongated spring 104 is shown coupled to the cover 130 and the compression mechanism 102 is disengaged (e.g., levers 106 are released in a free position and biasing elements 114 are unloaded). In FIG. 2, the elongated spring 104 is held in place on the outer surface 134 of cover 130 by retainers 118 with cavities sized to receive distal portions of outer arms 105 as described with reference to FIG. 1. When the outer arms 105 are secured (e.g., held, restrained, etc.) in retainers 118, the biasing elements 114 are constrained from horizontal or vertical movement, including when a torque is applied to the levers 106. The retainers 118 allow the biasing elements 114 to twist around a centerline axis of the bends, which form a groove across all of the bends, when a torque is applied to the levers 106 (either on the lever arms 107, or on the intermediate lever members 108, or on a combination thereof).

When the compression mechanism 102 is assembled on the cover 130, at least a portion of outer arms 105 and contact portions 110 are generally disposed in a first plane, which opposes, and is substantially parallel to, the outer surface 134 of cover 130. At least a portion of the outer arms 105 and the contact portions 110 are in contact with the outer surface 134 of the cover 130 both when the compression mechanism 102 is disengaged (e.g., levers are unrestrained in a free position and biasing elements are unloaded) and when the compression mechanism 102 is engaged (e.g., levers 106 are restrained in a fixed position and biasing elements 114 are loaded).

When the compression mechanism 102 is disengaged, as illustrated in FIG. 2, the lever arms of levers 106a, 106b, and 106c are generally disposed in a second plane, which traverses the first plane and the cover 130. The bend or turn of biasing elements 114 determines the angle between the planes. The angle measured between the planes when the compression mechanism 102 is disengaged corresponds to a ‘free angle’ of the elongated spring 104. As used herein, a ‘free angle’ is measured between the arms of a torsion spring when the spring is in an unloaded or free position. In the example elongated spring 104, each of the biasing elements 114 creates the same-size free angle (or substantially the same-size free angle) between two arms extended from that biasing element. In the example shown in FIG. 2, the pairs of arms defining the free angle include lever arm 107a and outer arm 105a, lever arm 107b and contact arm 111a, lever arm 107c and contact arm 111b, lever arm 107d and contact arm 111c, lever arm 107e and contact arm 111d, and lever arm 107f and outer arm 105b.

The free angle can be adjusted to increase or decrease pressure applied by the contact portions 110a, 110b when the biasing element is in the loaded position. Although a single bend or turn is illustrated in the figures, it should be apparent that any number of turns may be implemented in the biasing elements 114 to achieve the desired angle of rotation (e.g., angular deflection) measured from the unloaded position and/or the amount of torque that the spring exerts for the given angle (e.g., spring rate). In at least one example, the free angle may be between 30° and 45°.

FIG. 3 is a cutaway top, front, and side perspective view of the mechanical stack assembly 100 in an assembled arrangement. In FIG. 3, the levers 106 of the compression mechanism 102 are released from corresponding anchors 120 and cover 130 is transparent. FIG. 3 illustrates possible alignment of the contact portions 110 with components of memory module 140. In FIG. 3, each of the contact arms 111 is substantially parallel and vertically aligned with respective memory components 144. When the compression mechanism is engaged, a compressive force is applied by each of the contact arms 111. Thus, each of the memory components 144 receives pressure directly from the aligned contact arm. As a result, the compressive force is more evenly distributed across the memory components 144.

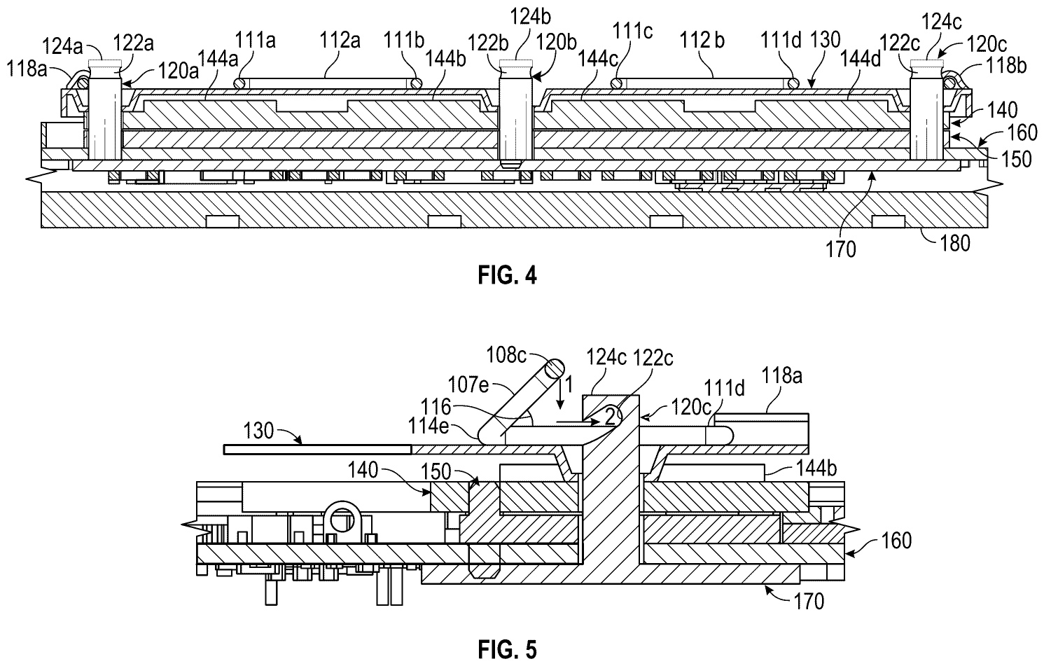

FIG. 4 is cross-sectional view of the mechanical stack assembly 100 in an assembled arrangement taken along lines A-A shown in FIG. 2. In addition to the cover 130, memory module 140, compressive connector 150, motherboard 160, and base 170, FIG. 4 also includes an example substrate 180, upon which the mechanical stack assembly 100 can optionally be mounted. FIG. 4 shows the three anchors 120 and one the indents 122a-122c therein. A cross-section of the contact portions 110 is also shown, with the contact arms 111 (in cross-section) and the intermediate contact members 112 (not in cross-section). A plane in which the contact portions 110 are disposed is substantially parallel to cover 130. Additionally, the contact arms 111 and intermediate contact members 112 oppose, and are in contact with, the outer surface 134 of cover 130.

FIG. 4 shows the vertical alignment (e.g., in the Z-direction) of the contact arms 111 with memory components 144, respectively, of the memory module 140. For example, contact arm 111a is aligned with memory component 144a, contact arm 111b is aligned with memory component 144b, contact arm 111c is aligned with memory component 144c, and contact arm 111d is aligned with memory component 144d. When the compression mechanism is engaged, and the levers are restrained by the indents 122 of anchors 120, this configuration causes pressure from each of the contact arms 111 to be applied via the cover 130 to a respective memory component 144a-144d. Thus, the memory components 144 receive more uniform pressure across the memory module 140.

FIG. 5 is a cross-sectional view of the mechanical stack assembly 100 in an assembled arrangement taken along lines B-B shown in FIG. 2. The second anchor 120b and the indent 122b formed in the second anchor are illustrated. The second anchor 120b extends from a lower end at the base 170 through through-holes 162b, 152b, 142b, and 132b of the motherboard 160, the compressive connector 150, the memory module 140, and the cover 130, respectively. FIG. 5 also shows the lever arm 107c (not in cross-section) and intermediate lever member 108b (in cross-section) of the second lever 106b. The contact arm 111b (not in cross-section) of contact portion 110a is also shown. Additionally, a free angle 116 defined by the lever arm 107c of the second lever 106b and the contact arm 111b of the first contact portion 110a, is shown. The free angle 116 is present when the compression mechanism is disengaged and the levers are not restrained by a corresponding anchor, as illustrated in FIG. 5 by second lever 106b and the corresponding second anchor 120b.

To transition the compression mechanism from disengaged to engaged, a torque is applied to one or more levers 106 to cause the lever arms 107 to rotate about corresponding biasing elements 114 as shown by directional arrow 1. When the intermediate lever members 108 are horizontally aligned with respective indents 122 in respective anchors 120 (e.g., when intermediate lever member 108b is aligned with indent 122b of anchor 120b), then a horizontal force may be applied to one or more of the levers 106 to move an interlocking section of each intermediate lever member 108a, 108b, 108c into a horizontally-aligned indent 122a, 122b, 122c of an anchor 120a, 120b, 120c. Once the interlocking section of an intermediate lever member is received in a corresponding indent, the hook shape of the indent (e.g., angled shape, curved shape, etc.) restrains the lever until appropriate forces in reverse are applied to the levers 106.

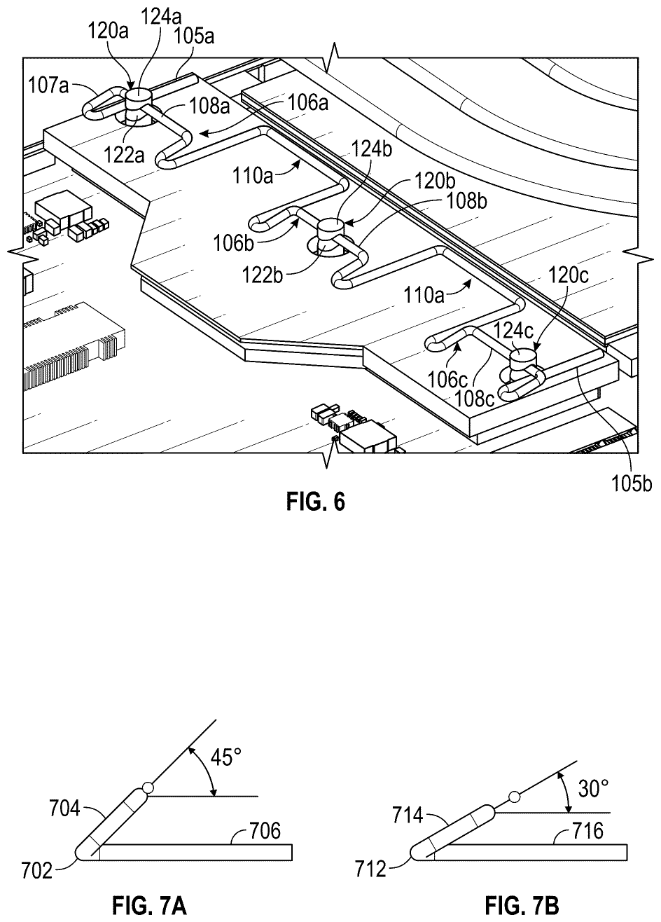

FIG. 6 is a cutaway top, front, and side perspective view of the assembled mechanical stack 100, in which the levers 106 of the compression mechanism 102 are restrained in a fixed position by the corresponding anchors 120. The retainers 118 are omitted in FIG. 6 for clarity. As shown in FIG. 6, an interlocking section of each of the intermediate lever members 108 is received in, and restrained by, one of the indents 122 of a corresponding anchor 120a-120c. In this example, the interlocking sections may have the same cross-section (e.g., same shape, same dimensions) as the remaining portions of the intermediate lever members 108. When the levers 106 are in the fixed position as shown, the biasing elements 114 are loaded in response to the twisting or bending movement that occurred as the levers were rotated and secured in the fixed position. The angular deflection corresponds to how far the lever arms are rotated from the free angle to be horizontally aligned with the indents of corresponding anchors.

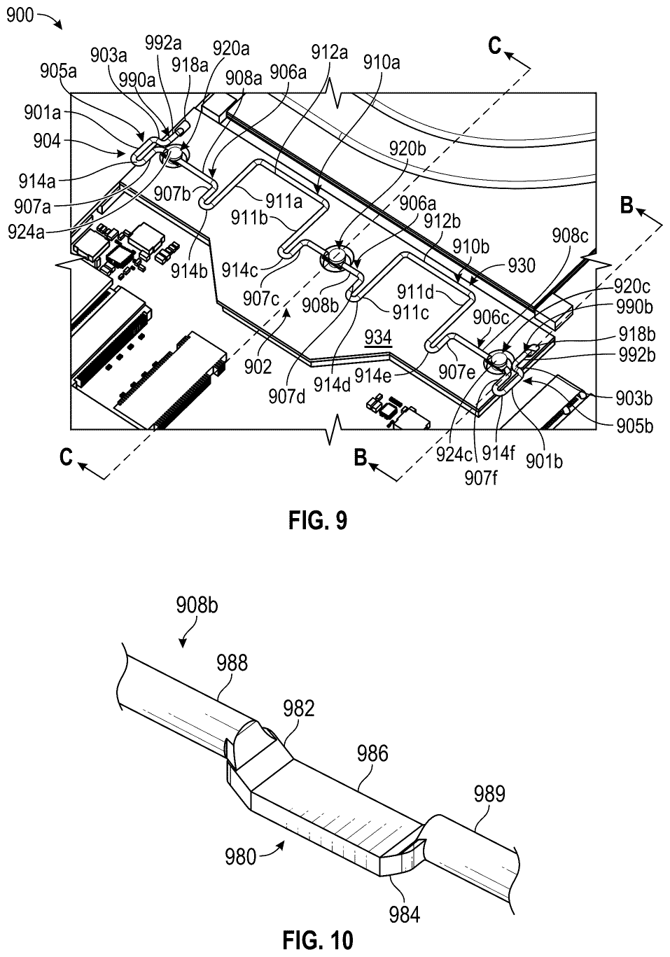

In other examples, the interlocking sections may have a different cross-section than the remaining portions of the intermediate lever members 108. For example, the interlocking sections could be shaped to mate with the upper portion of the anchor or connect in any other way that requires a different shape for the interlocking section to be releasably coupled with the anchor. In another example, the interlocking section may be offset from the remaining portions of the intermediate lever member as will be further described herein with reference to FIGS. 9-13.

In this example, outer arms 105 are substantially straight and stay within the edges of the cover 130. Thus, distal portions of the outer arms 105 can be received within retainers (shown in FIGS. 1, 2, 5) at the edges of the cover 130. In this example, the biasing elements 114a, 114f at opposite ends of the elongated spring 104 are coupled to the outer arms 105a, 105b, respectively, and are turned to work in the same direction as adjacent biasing elements 114b, 114e, which results in lever arms 107a, 107f crossing the outer arms 105a, 105b, respectively. This design may advantageously limit the lateral (X-direction) footprint of the cover, memory module, and possibly other layers. In other examples, modifications could be made in order to allow the biasing elements 114a, 114f at opposite ends of the elongated spring 104 to be turned in an opposite directions such that the outer lever arms 107a and 107f do not cross outer arms 105a, 105b. For example, one modification includes adjusting the through-holes of the cover (and other layers) to allow more space at the ends of the cover. Another modification includes extending the cover to allow more space at the ends of the cover. Further modifications could include changing the outer arm design in various ways, one example of which will be further shown and described with respect to FIG. 12.

FIGS. 7A-7B are side views of possible free angles along a groove of an elongated spring, such as elongated spring 104, when the compression mechanism is disengaged and the levers of the elongated spring are in a free position. FIG. 7A illustrates a biasing element 702 (e.g., similar to biasing elements 114) with a first end extending into a lever arm 704 (e.g., similar to lever arms 107) and a second end extending into a contact arm 706 (e.g., similar to contact arms 111). Alternatively, the second end of the biasing element could extend into an outer arm (e.g., similar to outer arms 105) or a connecting arm (e.g., connecting the biasing element to another lever arm, a contact arm, or an outer arm). The example free angle along the groove shown in FIG. 7A is 45°. Similarly, FIG. 7B illustrates a biasing element 712, a lever arm 714, and a contact arm 716 (or an outer arm or other connecting arm). The example free angle along the groove shown in FIG. 7B is 30°.

The permissible angle of deflection (e.g., the degree of allowable displacement) is dependent on the particular design of the elongated spring. For example, the angle of deflection of elongated spring 104 of FIGS. 1-6 may be limited by the diameter of the outer arms, as the adjacent lever arms cross the outer arms. Thus, the maximum angle of deflection of a spring designed with the free 45° angle shown in FIG. 7A would be less than 45°, and the maximum angle of deflection of a spring designed with the free 30° angle shown in FIG. 7B would be less than 30°. In other examples, however, where no lever arms cross another arm (e.g., as will be described with reference to FIGS. 9-13), the maximum angle of deflection could be less than or equal to the free angle.

The free angle of the groove can be adjusted to increase or decrease the pressure applied by the contact portions based on the particular needs and requirements of a PCB that receives the pressure and/or other layers in a mechanical stack assembly with the PCB. The load of the elongated spring refers to the force exerted by the spring (e.g., the contact portions of the elongated spring) when the biasing elements are twisted from a free position. The load of an elongated spring as described herein will be proportional to the angle of deflection that enables the levers to be restrained by corresponding anchors.

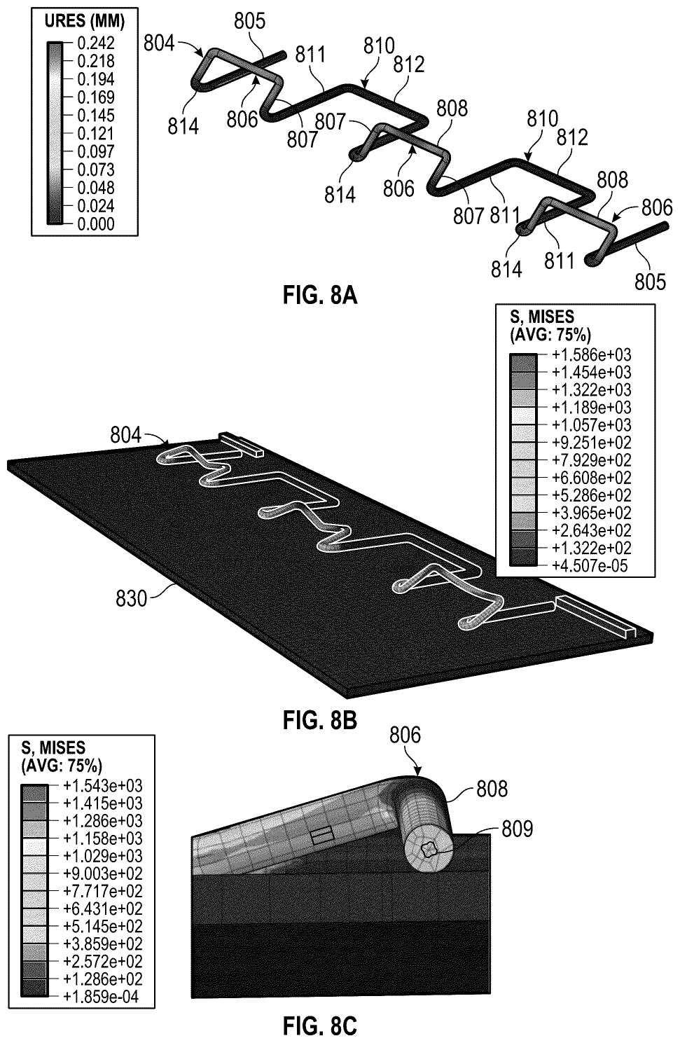

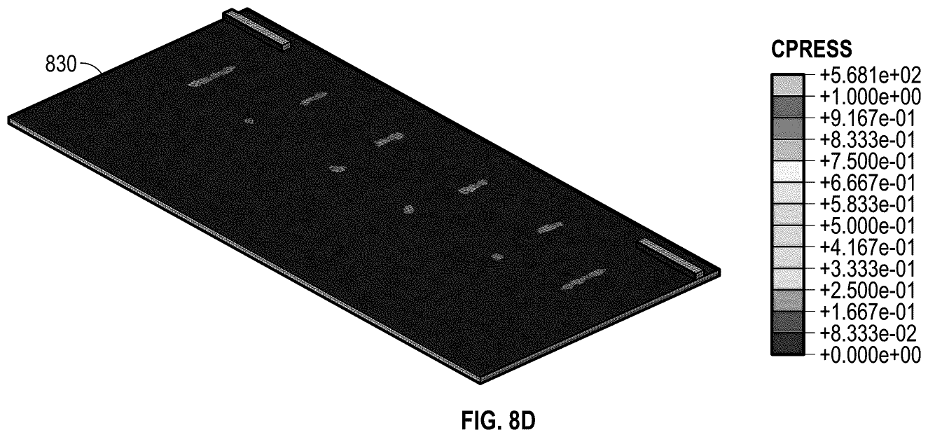

FIGS. 8A-8D are diagrams illustrating results of a structural analysis of a simulated elongated spring 804 (e.g., similar to elongated spring 104) of a compression mechanism as disclosed herein. FIGS. 8A-8D illustrate the structural analysis results based on von Mises stress testing of the simulated elongated spring 804. The von Mises stress is a yield criterion to determine whether a given material will yield or fracture.

FIG. 8A shows the resultant displacement (URES) of the various parts of simulated elongated spring 804 measured in millimeters. The simulated elongated spring 804 includes levers 806, lever arms 807, intermediate lever members 808, contact portions 810, contact arms 811, intermediate contact members 812, outer arms 805, and biasing elements 814.

FIG. 8B shows the simulated elongated spring 804 mounted on a simulated cover 830 and the Mises yields. The lever arms, the interlocking sections of the intermediate lever members, and the biasing elements show the greatest Mises yields (e.g., in the range of +1.057e+03 to +5.286e+02). The contact arms and intermediate contact members show the least Mises yields (e.g., in the range of +4.507e-05 and below).

FIG. 8C is a cross-sectional view of an interlocking section of an intermediate lever member 808 of FIG. 8B. A center 809 of the intermediate lever member 808 shows the greatest Mises yield (e.g., in the range of +1.029e+03 to +1.513e+03).

Based on the simulation results shown in FIGS. 8A-8C, an elongated spring as proposed herein (e.g., elongated spring 104) provides additional compressive force compared to a typical screw. For example, a torsional spring can apply approximately 82 pounds of compressive force, whereas a typical screw can apply approximately 45 pounds of compressive force.

FIG. 8D illustrates a pressure point analysis of the simulated elongated spring 804 and cover 830. FIG. 8D shows the simulated cover 830 (without the elongated spring 804) after the simulated testing was performed. On the simulated cover 830, lighter contrast areas represent pressure points from the elongated spring 804 when torque was applied to the levers 806. As shown in FIG. 8D, pressure is more evenly distributed across the cover 830 where the contact portions 810 applied a compressive force. Indeed, more than eight pressure points are observed in FIG. 8D as compared to three pressure points of a typical mechanical stack assembly with LPCAMM memory modules. Thus, when implemented in a mechanical stack assembly with a memory module such as memory module 140, an elongated spring similar to elongated spring 804 results in pressure points over each memory component of the memory module. Moreover, the particular design of the elongated spring can be modified to ensure that the contact portions are aligned with components or other areas where a compressive force is desired and/or needed.

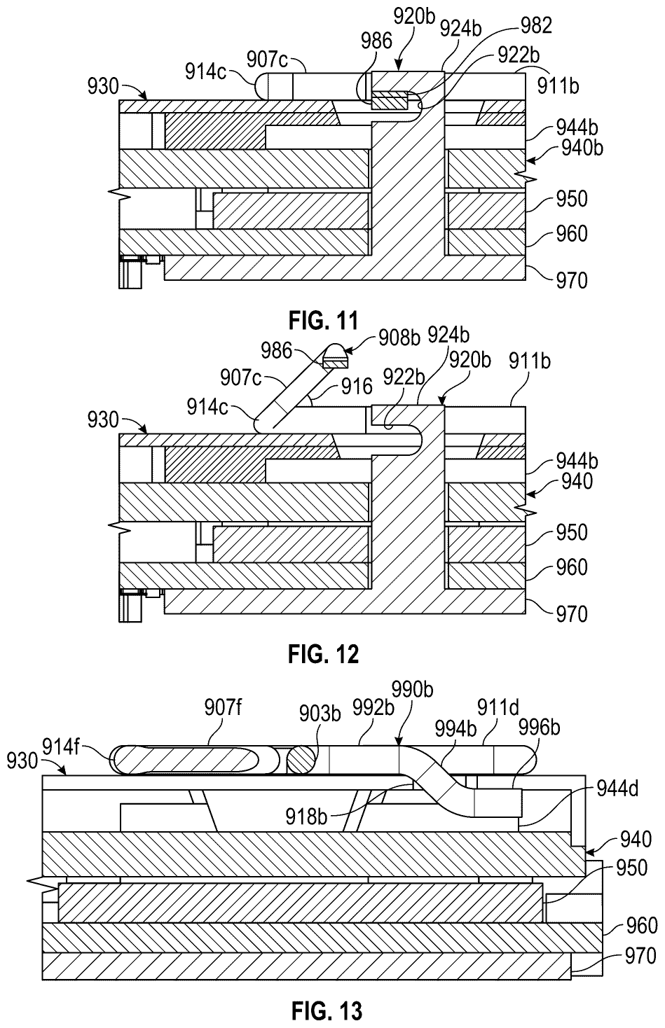

FIG. 9 is a cutaway top, front, and side, perspective view of an assembled mechanical stack assembly 900. The mechanical stack assembly 900 includes an alternative embodiment of a compression mechanism 902, which includes an elongated spring 904 with levers 906a, 906b, and 906c (collectively referenced as 906) and contact portions 910a and 910b (collectively referenced as 910). In FIG. 9, the levers 906 are restrained by corresponding anchors 920a, 920b, and 920c (collectively referenced as 920) and are releasable from the anchors in response to appropriate forces. The mechanical stack assembly 900 (e.g., similar to mechanical stack assembly 100) may include a cover 930 and a base 970 (shown in FIGS. 11-13) from which the anchors 920 extend.

Although elongated spring 904 is illustrated with three levers 906 and two contact portions 910 in an alternating arrangement with biasing elements 914a, 914b, 914c, 914d, 914e, 914f (collectively referenced as 914) coupled therebetween, the number of levers and contact portions, and the placement thereof within the elongated spring 904, may vary depending on the particular configuration of the mechanical stack assembly and components upon which a compressive force is to be applied.

Generally, the levers 906 may be similar to levers 106, such as including respective pairs of lever arms 907a-907b, 907c-907d, and 907e-907f (collectively referenced as 907) and respective intermediate lever members 908a, 908b, and 908c (collectively referenced as 908). The intermediate lever members 908 connect respective pairs of lever arms 907a-907b, 907c-907d, and 907e-907f to form 3-sided, generally rectangular levers 906. In other examples, however, levers 906 can be any suitable shape including, but not limited to, U-shapes, curved shapes, spline shapes, ellipsoid shapes, trapezoidal shapes, etc., as will be further described herein with reference to FIGS. 14A-14D.

Intermediate lever members 908 each include an interlocking section that is received in an indent formed in one of the anchors 920. The interlocking sections of the intermediate lever members 908 are vertically offset lower or below the intermediate lever members 908.

The contact portions 910 may be similar to contact portions 110, such as having respective pairs of contact arms 911a-911b and 911c-911d (collectively referenced as 911), and with respective intermediate contact members 912a and 912b (collectively referenced as 912). The intermediate contact members 912 connect respective pairs of contact arms 911a-911b and 911c-911d to form 3-sided, generally rectangular contact portions 910. In other examples, however, the contact portions 910 can be any suitable shape including, but not limited to, U-shapes, curved shapes, spline shapes, ellipsoid shapes, trapezoidal shapes, etc., some examples of which will be further described herein with reference to FIGS. 14A-14D.

The biasing elements 914 may be similar to biasing elements 114, where one biasing element is provided at the end of each of the lever arms 907, such that the biasing elements 914 are aligned along a common axis about which the levers can be rotated to a certain angular deflection. In one example, the biasing elements 914 form a torsional spring (or any other suitable spring type) where each biasing element is shaped as a single bend or turn of a rod (e.g., bar, shaft, wire, etc.) that works (e.g., responds to rotational movement of a lever arm by twisting, turning, etc.) in a clockwise or counterclockwise direction. One end of a given biasing element (e.g., 914a) extends into a lever arm (e.g., 907a) and an opposite end of the biasing element extends into another arm biased against the lever arm. As shown in FIG. 9, the other arm is either a contact arm of an adjacent contact portion or an outer arm (e.g., 905a) that is used to couple the elongated spring 904 to the cover 930. In other embodiments, the other arm may be a connecting arm (not shown) to another lever, or a connecting arm to a contact portion.

In the elongated spring 904 of FIG. 9, each pair of biasing elements 914a-914b, 914c-914d, and 914e-914f, coupled to levers 906a, 906b, and 906c, respectively, may be turned to work in opposing directions. A first biasing element 914a connects and biases a first outer arm 905a to the lever arm 907a of the first lever 906a such that the first biasing element 914a works in the second direction (e.g., counterclockwise). A second biasing element 914b connects and biases the lever arm 907b of the first lever 906a to the contact arm 911a of the first contact portion 910a such that the second biasing element 914b works in the first direction (e.g., clockwise). A third biasing element 914c connects and biases the lever arm 907c of the second lever 906b to contact arm 911b of the first contact portion 910a such that the third biasing element 914c works in the second direction (e.g., counterclockwise). A fourth biasing element 914d connects and biases the lever arm 907d of the second lever 906b to contact arm 911c of the second contact portion 910b such that the fourth biasing element 914d works in the first direction (e.g., clockwise). A fifth biasing element 914e connects and biases the lever arm 907e of the third lever 906c to contact arm 911d of the second contact portion 910b such that the fifth biasing element 914e works in the second direction (e.g., counterclockwise). A sixth biasing element 914f connects and biases the lever arm 907f of the third lever 906c to a second outer arm 905b such that the sixth biasing element 914f works in the first direction (e.g., clockwise). In other embodiments, the work (e.g., twist) direction of the biasing elements 914 may be only clockwise, only counterclockwise, or any combination thereof.

The outer arms 905a, 905b are configured to allow the biasing elements 914a, 914f to be turned such that lever arms 907a, 907f do not cross adjacent outer arms 905a, 905b. In this example, outer arms 905a and 905b each include a first longitudinal extension 901a, 901b, a lateral extension 903a, 903b, and a second longitudinal extension 990a, 990b. The first longitudinal extensions 901a, 901b are proximal to respective biasing element 914a, 914f and are disposed laterally outward from respective edges of the cover 930. The second longitudinal extensions 990a, 990b are laterally offset from the first longitudinal extensions 901a, 901b by the lateral extensions 903a, 903b, such that the second longitudinal extensions 990a, 990b are vertically aligned with the cover 930. In other configurations, where a greater distance extends between the edge of the edges of the cover 930 and the anchors 920a, 920c closest to the edge of the cover 930 (e.g., when the cover is larger, when the anchors are placed further from the edge of the cover, etc.), the lateral extensions may be omitted so that the second longitudinal extensions 990a, 990b are not laterally offset from the first longitudinal extensions 901a, 901b.

The elongated spring 904 may be secured, positioned, and/or aligned on an outer surface 934 of cover 930 with retainers (e.g., securing mechanisms, fasteners, clips, lugs, clamps, openings, indents, cavities, etc.) that are coupled to and/or defined by the structure (e.g., molded, stamped, cast, bent, assembled, etc.) of the cover 930, as previously described herein with respect to cover 130. In the example shown in FIG. 9, openings 918a and 918b (collectively referenced as 918) are formed in cover 930 and sized to slidably receive part of the second longitudinal extensions 990a and 990b (collectively referenced as 990) of the outer arms 905, respectively. The second longitudinal extensions 990 include proximal portions 992b, angled portions (e.g., angled portion 994b shown in FIG. 13), and distal portions (e.g., distal portion 996b shown in FIG. 13). The angled portions provide vertical offsets from the proximal portions 992a, 992b to enable the distal portions (e.g., distal portion 996b) to be received in respective openings 918a, 918b in the cover 930.

The compression mechanism 902 also includes anchors 920 (e.g., similar to anchors 120) to releasably restrain (e.g., lock, hold, constrain, retain, etc.) levers 906, respectively, in a fixed position. In an example, anchors 920 extend from respective lower ends at a base (e.g., bottom plate, base plate, back plate, bottom, bottom cover, base cover, etc.) through the cover 930 to respective upper ends (e.g., upper end 924a shown in FIG. 9 and upper end 924b shown in FIGS. 11-12) that are vertically spaced (e.g., Z-axis) above cover 930. In one example, anchors 920 may be formed as vertical shafts (e.g., standoffs, rods, cylinders, etc.) coupled to and/or defined by the structure (e.g., stamped, bent, extruded, etc.) of the base 970.

Each anchor 920a, 920b, and 920c includes a respective upper portion with an indent (e.g., notch, opening, aperture, hook cavity, etc.), sized to receive an interlocking section of an adjacent intermediate lever member 908a, 908b, 908c of levers 906, to couple the levers 906 to the anchors 920 such that the elongated spring is loaded (e.g., prevented from rotating) and the levers 906 are restrained in a fixed position until an appropriate releasing force is applied to the levers 906. The upper portions of the anchors terminate at upper ends of the anchor, which are vertically spaced above the cover 930. When the levers 906 are restrained in a fixed position by the anchors 920, biasing elements 914 are loaded and a compressive force is applied to the cover 930 by contact portions 910. In compression mechanism 902, upper ends 924 are substantially horizontally aligned with an upper edge or upper surface of the levers 906, when the levers are restrained in the fixed position. An example anchors (e.g., anchor 920b) including an indent (e.g., indent 922) and an upper end (e.g., upper end 924b) is illustrated in FIGS. 11-12.

FIG. 10 is a cutaway perspective view showing more details of the intermediate lever member 908b including an extension link 980 formed therein. The intermediate lever member 908b includes a first intermediate extension 988, a second intermediate extension 989, and the extension link 980, which is disposed between the first and second intermediate extensions 988 and 989. The extension link 980 includes a first transition portion 982, a second transition portion 984, and an offset portion 986 that is vertically offset from the first and second intermediate extensions 988 and 989 by the first and second transition portions 982 and 984, respectively, disposed at opposite ends of the offset portion 986. The offset portion 986 may be an interlocking section that is sized to be received in an indent of the adjacent anchor 920b. The vertical offset of the offset portion 986 allows the height of the anchor 920b to be reduced. In an example, the offset portion 986 is flattened to enable further height reduction of anchor 920b.

The design of intermediate lever member 908b with the extension link 980 may result in a thickness (e.g., Z-height) reduction of the anchors by 0.5 to 1.0 mm, or potentially more. Thus, the upper end 924b of the anchor 920b may be substantially horizontally aligned with an upper edge or surface of the elongated spring 904. Thus, the tallest point in the mechanical stack assembly 900 may be defined by the diameter of the elongated spring 904 (or the levers 906 of the elongated spring 904). Extension link 980 is representative of other extension links formed in the other intermediate lever members 908a and 908c of the elongated spring 904. However, placement of the extension links along the respective intermediate lever members 908 may vary (e.g., closer to one lever arm or the other lever arm, in the middle, etc.).

It should be noted that references to the first intermediate extension 988 and the second intermediate extension 989 may include the first lever arm (e.g., first lever arm 907c) and the second lever arm (e.g., second lever arm 907d) of the particular lever (e.g., lever 906b), respectfully. For example, alternative designs of the levers (e.g., curved, arched, U-shaped, etc.) may include curved lever arms extending from respective biasing elements to opposite ends of the extension link (e.g., extension link 980).

FIG. 11 is a cross-sectional view of the assembled mechanical stack assembly taken along lines C-C of FIG. 9. FIG. 11 shows the lever 906b restrained in a fixed position by anchor 920b. FIG. 11 further illustrates possible layers of the mechanical stack assembly 900 including the cover 930, a memory module 940 with a memory component 944b (e.g., LPCAMM), a compressive connector 950, a motherboard 960, and a base 970. The second anchor 920b and the indent 922b formed in the second anchor are illustrated.

The second anchor 920b extends from a lower end at the base 970 through through-holes of the motherboard 960, the compressive connector 950, the memory module 940, and the cover 930, respectively. FIG. 11 also shows the lever arm 907c (not in cross-section) and the third portion 986 of extension link 980 of intermediate lever member 908b (in cross-section) of the second lever 906b. The third portion 986 is disposed in the indent 922b of anchor 920b, which restrains the second lever 906b in a fixed position. The contact arm 911b (not in cross-section) of contact portion 910a is also shown. The angle of lever 906b is at maximum deflection in the fixed position.

As shown in FIG. 11, the upper end 924b of anchor 920b is horizontally aligned with an upper surface or upper edge of the second lever 906b (or at least the intermediate extensions 988, 989 of the intermediate lever member 908b) when the second lever is in the fixed position. In some scenarios, the upper ends of anchors 920 may be vertically spaced below the upper surface or upper edge of the levers 906 (or at least the intermediate extensions of intermediate members 908) when the levers 906 are in a fixed position. In the fixed position, the upper edge or surface of the second lever (or at least the intermediate extensions 988, 989) is vertically spaced above the outer surface 934 of the cover 930 by the diameter of the shaft, rod, wire, etc. from which the elongated spring 904 is formed. Thus, for implementations where Z-height of the mechanical stack assembly 900 is critical, the anchors 920 may be sized so that the height of the assembly is defined by the diameter of the elongated spring 904, rather than the anchors. By way of example, the diameter of the elongated spring 904 may be in a range of 0.5-2 millimeters (mm) (e.g., for thin laptops or other thin devices). For thicker devices (e.g., workstations, gaming laptops, etc.) the diameter of the elongated spring 904 could be up to 3 mm or possibly more. In some scenarios, the levers 906 may be formed to have a different diameter than the contact portions 910 and/or the outer arms 905.

To transition the compression mechanism from engaged to disengaged, a torque is applied to one or more levers 906 to cause the lever arms 907 to slide laterally away from the anchors 920. This releases the torque applied to the third portions (e.g., third portion 986) of the extension links (e.g., extension link 980) of intermediate lever members 908, and thus the levers 906 can rotate about the corresponding biasing elements 914 to a free position. Additionally, a free angle 916 defined by the lever arm 907c of the second lever 906b and the contact arm 911b of the first contact portion 910a, is shown. The free angle 916 is present when the compression mechanism is disengaged and the levers are not restrained by a corresponding anchor.

FIG. 12 is another cross-sectional view of the assembled mechanical stack assembly 900 taken along lines C-C of FIG. 9, but instead of showing the levers 906 in a fixed position, FIG. 12 shows the levers in a free position. To transition the compression mechanism 902 from disengaged to engaged, a torque is applied to one or more levers 906 to cause the lever arms 907 to rotate about corresponding biasing elements 914 as shown by directional arrow 1. When the third portions of the intermediate lever members 908 are horizontally aligned with respective indents 922 in respective anchors 920 (e.g., when the third portion 986 of extension link 980 in the intermediate lever member 908b is aligned with indent 922b of anchor 920b), then a horizontal force may be applied to one or more of the levers 906 to move the offset portions of the extension links of the intermediate lever members 908 into horizontally-aligned indents 922 of anchors 920. Once the offset portion of an extension link of an intermediate lever member is received in a corresponding indent, the hook shape of the indent (e.g., angled shape, curved shape, etc.) restrains the lever until appropriate forces in reverse are applied to the levers 906.

FIG. 13 is a cross-sectional view of the assembled mechanical stack assembly 900 taken along lines D-D of FIG. 9. In FIG. 13 the levers 906 are restrained in a fixed position by anchors 920. Lever arm 907f of the third lever 906c is shown in FIG. 13 and is restrained in the fixed position by the third anchor 920c. FIG. 13 further shows the example layers of the mechanical stack assembly 900 including the cover 930, the memory module 940 with a memory component 944d (e.g., LPCAMM), the compressive connector 950, the motherboard 960, and the base 970.

An example coupling of the outer arm 905b of the elongated spring 904 to the cover 930 is illustrated in FIG. 13. The second longitudinal extension 990b of the second outer arm 905b includes the proximal portion 992b, an angled portion 994b, and a distal portion 996b. The proximal portion 992b is substantially parallel to and engages the outer surface 934 of cover 930. The angled portion 994b is sized to be received in the second opening 918b and traverses the outer surface 934 of the cover 930. The angled portion 994b extends between the proximal portion 992b and distal portion 996b. Thus, the angled portion 994b vertically offsets the distal portion 996b from the proximal portion 992b. The distal portion 996b is sized to be received in the second opening 918b. The distal portion is inserted into the second opening 918b and maneuvered such that the proximal portion rests on the outer surface 934 of the cover 930, the angled portion 994b traverses the outer surface 934 of the cover 930, and the distal portion 996b is secured below and substantially parallel to the outer surface 934 of the cover 930. The second longitudinal extension 990a (partially shown in FIG. 9) of the first outer arm 905a may be similarly configured and may be similarly secured on the opposite side of the cover 930 in the first opening 918a.

FIGS. 14A-14D depict alternative example elongated springs for a compression mechanism that may be implemented in examples disclosed herein. The elongated springs in FIGS. 14A-14D are illustrated in line drawings for simplicity. It should be appreciated, however, that the elongated spring could be formed from a bar, rod, shaft, wire, etc. having a selected diameter (or different diameters for different portions of the spring). Any of the example features and/or aspects of FIGS. 14A-14D can be utilized in conjunction with or in lieu of any of the examples disclosed herein. In the examples shown in FIGS. 14A-14D, representative reference numbers are provided on selected elements for simplicity, and those reference numbers are intended to apply to other similar elements shown in the FIGURE.

In FIG. 14A, an example elongated spring 1400 is illustrated with outer arms 1405, three levers 1402, two contact portions 1406, and six biasing elements 1409. The levers 1402 and the contact portions 1406 are three-sided shapes. Each lever 1402 includes two converging lever arms 1403 and an intermediate lever member 1404 connecting the converging ends of the two lever arms 1403. Each contact portion 1406 includes two converging contact arms 1407 and an intermediate contact member 1408 connecting the converging ends of the two contact arms. Each biasing element 1409 is located between either a lever arm 1403 and a contact arm 1407 or between a lever arm 1403 and an outer arm 1405.

In FIG. 14B, an example elongated spring 1410 is illustrated with outer arms 1415, three levers 1412, two contact portions 1416, and six biasing elements 1419. The levers 1412 and the contact portions 1416 are three-sided shapes. Each lever 1412 includes two converging lever arms 1413 and an intermediate lever member 1414 connecting the converging ends of the two lever arms 1413. Each contact portion 1416 includes two substantially parallel contact arms 1417 and an intermediate contact member 1418 connecting two ends of the two contact arms of the contact portion 1416. Each biasing element 1419 is located between either a lever arm 1413 and a contact arm 1417 or between a lever arm 1413 and an outer arm 1415.

In FIG. 14C, an example elongated spring 1420 is illustrated with outer arms 1425, two levers 1422, three contact portions 1426, and four biasing elements 1429. The levers 1422 and the contact portions 1426 are three-sided shapes. Each lever 1422 includes two substantially parallel lever arms 1423 and an intermediate lever member 1424 connecting two ends of the two lever arms 1423 of the lever 1422. Each contact portion 1426 includes two substantially parallel contact arms 1427 and an intermediate contact member 1428 connecting two ends of the two contact arms of the contact portion 1426. Each biasing element 1429 is located between a lever arm 1423 and a contact arm 1427. A bend or turn 1421 of the elongated spring connects the outer arms 1425 to adjacent contact arms without a biasing element being disposed therebetween.

In FIG. 14D, an example elongated spring 1430 is illustrated with outer arms 1435, two levers 1432, three contact portions 1436, and four biasing elements 1439. The levers 1432 and the contact portions 1436 are three-sided shapes. Each lever 1432 includes two substantially parallel lever arms 1433 and an intermediate lever member 1434 connecting two ends of the two lever arms 1433 of the lever 1432. Each contact portion 1436 includes two converging contact arms 1437 and an intermediate contact member 1438 connecting two converging ends of the two contact arms 1437 of the contact portion 1436. Each biasing element 1439 is located between a lever arm 1433 and a contact arm 1437. A bend or turn 1431 of the elongated spring connects the outer arms 1435 to adjacent contact arms without a biasing element being disposed therebetween.

In each of the above examples, any number of variations are within the scope of the present disclosure. For example, any suitable number of levers (e.g., one, two, three, four, or more), any suitable number of contact portions (e.g., one, two, three, four, or more), and any suitable combination thereof may be configured in an elongated spring. In another example, some configurations may include adjacent levers and/or adjacent contact portions. In yet further examples, one or more intermediate arms may be used to connect a lever to an adjacent contact portion, a lever to an adjacent lever, a lever to an adjacent outer arm, a contact portion to an adjacent contact portion, or a contact portion to an adjacent outer arm. In yet further examples, the length of the lever arms may be a shorter length than the contact arms (as shown in the examples herein), the same length as the contact arms, or a greater length than the contact arms. In yet further examples, the levers and/or the contact portions could have alternative shapes including, but not limited to, an arched shape, a U-shape, a diverging shape (e.g., diverging lever arms, diverging contact arms), an S-shape, or any other alternative shape that allows at least some portion of the contact arms and/or intermediate contact members to be vertically aligned with electronic components or other elements that are to be compressed in the mechanical stack assembly by the compression mechanism.

Additionally, FIGS. 14A-14D illustrated outer arms 1405, 1425, 1425, and 1435 as substantially straight extensions from respective biasing elements coupled to lever arms (e.g., FIGS. 14A-14B) or from an end of a contact arm (e.g., FIGS. 14C-14D). The outer arms, however, may be configured in any suitable manner and/or shape (e.g., outer arms 905, etc.) to achieve the intended purpose of coupling the elongated spring to a cover such that the common axis of the biasing elements is substantially fixed as the levers are rotated and releasably restrained by the anchors.

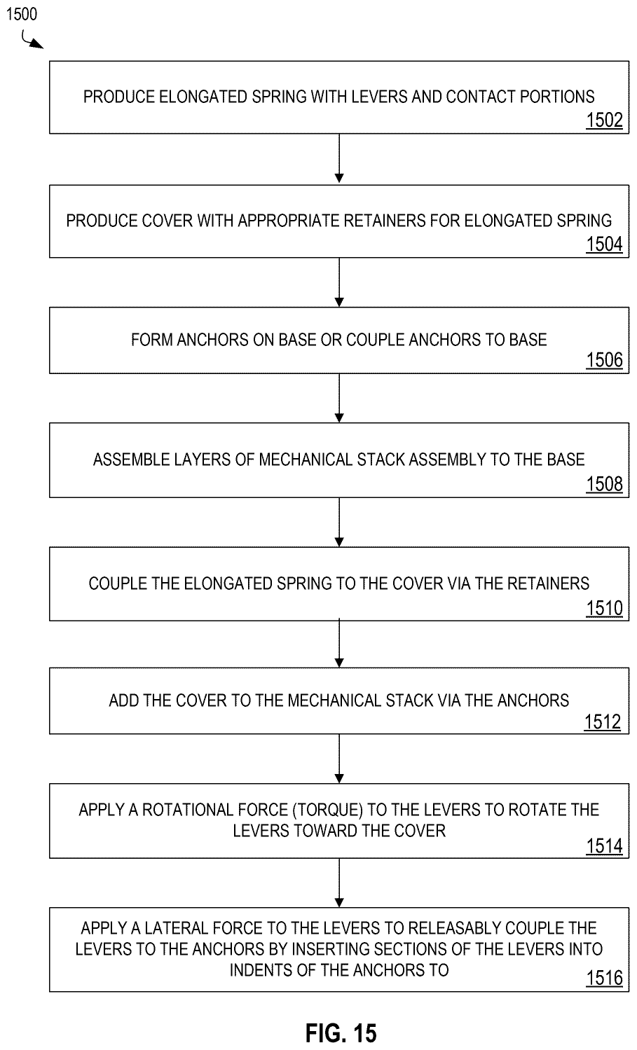

FIG. 15 is a flow diagram of an example process 1500 associated with producing examples disclosed herein. The example process can be used to produce, manufacture, assemble, and/or retrofit examples disclosed herein on a mechanical stack assembly and/or a computing device and/or a PCB. Thus, the example process 1500 can be implemented during manufacturing, assembly, or updating and/or retrofitting processes for computing devices, mechanical stack assemblies, and/or PCBs.

At 1502, an elongated spring (e.g., elongated spring 104, 904) is produced with levers (e.g., levers 106, 906), contact portions (e.g., contact portions 110, 910), biasing elements (e.g., biasing elements 114, 914), and outer arms (e.g., outer arms 105, 905). In this example, three levers and two contact portions alternate and two outer arms formed on or coupled to opposing ends. A biasing element is formed on or coupled between each lever and an adjacent contact portion, outer arm, or other arm, where the other arm could be connected to another lever, contact portion or outer arm.

At 1504, a cover is produced or retrofitted with retainers (e.g., retainers 118, openings 918) to secure the elongated spring to the cover (e.g., cover 130, 930). The retainers may be coupled to or defined by the structure of the cover. For example, the retainers may be housing structures (e.g., retainer 118) attached or formed on opposite sides of an outer surface (e.g., 134) of the cover. In another example, the retainers may be formed as openings (e.g., openings 918) formed at opposite sides of the outer surface of the cover. The retainers are sized to receive distal portions (e.g., distal portion 996b) of the outer arms.

At 1506, anchors (e.g., anchors 120, 920) are formed on or coupled to a layer in a mechanical stack, such as a base (e.g., base 170, 970). The anchors extend vertically upward from the base and are sized to pass through through-holes in one or more layers to be included in the mechanical stack. Additionally, the anchors are vertically sized to extend past the outer surface of the cover, when the other layers are disposed between the base and the cover. In some examples, the upper ends of the anchors extend past the contact portions of the elongated spring secured to the cover. In other examples, the upper ends of the anchors are substantially horizontally aligned with an upper edge or surface of the levers (or at least the intermediate extensions of the intermediate lever members) when the levers are restrained by the anchors. The anchors each include an indent (e.g., a hook cavity, notch, opening, etc.). The indent of a given anchor is shaped to receive an interlocking section of an adjacent lever to couple the adjacent lever to the given anchor and restrain the adjacent lever in a fixed position.

At 1508, the layers of the mechanical stack are assembled to the base. In one example, the layers include the cover, a memory module (e.g., memory module 140, 940), a compression connector (e.g., compression connector 150, 950), a motherboard (e.g., motherboard 160, 960), a heat gasket, etc. or any combination thereof. In this example, the through-holes of the motherboard can be aligned with the anchors. The motherboard can then be lowered onto and coupled to the base by the anchors. The through-holes of the compression connector can be aligned with the anchors. The compression connector can then be lowered onto the motherboard and coupled to the base by the anchors. The through-holes of the memory module can be aligned with the anchors. The memory module can then be lowered onto the compression connector and coupled to the base by the anchors.

At 1510, the elongated spring is coupled to the cover via the retainers. For example, distal portions of the outer arms of the elongated spring can be slidably inserted into the retainers formed on or coupled to the outer surface of the cover. In another example, distal portions of the outer arms of the elongated spring can be inserted into the openings in the cover to couple the elongated spring to the cover.

At 1512, the cover can be added to the mechanical stack. The through-holes of the cover are aligned with the anchors on the base. The cover, along with the elongated spring coupled to the cover, can then be lowered onto the memory module (or a heat gasket) and coupled to the base by the anchors.

At 1514, after the stack is assembled, a rotational force (e.g., a torque) can be applied to one or more of the levers to rotate the levers toward the outer surface of the cover. As one lever is rotated, the other levers also may rotate, but additional torque may need to be applied to one or more of the other levers to ensure that all levers have sufficient angular deflection to be horizontally aligned with the indents of the anchors, respectively.

At 1516, a lateral force is applied to the deflected levers to insert extension links of intermediate lever members (e.g., 208, 908) into indents of corresponding anchors and fixed within the indents such that the levers are restrained in a fixed position such that the levers are releasably coupled to the anchors. To release the levers, reverse forces can be applied. In some instances, a rotational force may be applied to free the inserted sections of the levers from the indents, and then a reverse lateral force can be applied to remove the inserted sections of the levers from the indents. Once the inserted sections are removed from the anchors, the rotational force can be removed (if still present) and the levers rotate back to the free position. The forces applied to the levers may be performed by a human or by a machine, or by a combination thereof. In one example, a user can push the levers down and into the indents of the anchor.

Once the mechanical stack is assembled and the elongated spring is restrained by the anchors in a fixed position, a reverse process may be used to dismount the cover and access the memory module (e.g., replace/repair selected memory components, etc.) or other layers.

It should be noted that some, none, or all of the activities described with reference to process 1500 may be performed by, or assisted by, humans. Additionally, some or all of the activities may be performed by, or assisted by, machines (e.g., automated, semi-automated, manual, or any suitable combination thereof).

A compression mechanism (e.g., compression mechanisms 102, 902) may be implemented with any suitable mechanical stack assembly in which compression is used. In some scenarios, existing mechanical stacks can be modified or retrofitted to implement a compression mechanism as disclosed herein. To modify an existing stack, for example, screws can be removed to reveal through-holes in the stack layers, retainers can be coupled to a cover or a new cover with retainers formed therein may be produced, anchors may be coupled to a base (e.g., in the threaded holes that typically receive screws) or a new base with anchors formed therein can be produced, and an elongated spring can be coupled to the cover via the retainers. The layer can then be assembled as described in process 1500. Although compression mechanisms 102, 902 have been described herein with reference to stacks that include memory modules (e.g., LPCAMM), it should be appreciated that numerous other types of mechanical stacks could be modified, retrofitted, or organically designed to implement a compression mechanism 102, 902. In one nonlimiting example, land grid array (LGA) based applications can be replaced by a compression mechanism as disclosed herein.

With regard to this specification generally, unless expressly stated to the contrary, use of the phrases ‘at least one of’ and ‘one or more of’ refers to any combination of the named elements, portions, levers, retainers, openings, conditions, activities, devices, etc. For example, ‘at least one of X, Y, and Z’ and ‘one or more of X, Y, and Z’ is intended to mean any of the following: 2) at least one X, but not Y and not Z; 2) at least one Y, but not X and not Z; 3) at least one Z, but not X and not Y; 4) at least one X and at least one Y, but not Z; 5) at least one X and at least one Z, but not Y; 6) at least one Y and at least one Z, but not X; or 7) at least one X, at least one Y, and at least one Z.

Additionally, unless expressly stated to the contrary, the terms ‘first’, ‘second’, ‘third’, etc., are intended to distinguish the particular items (e.g., elements, levers, portions, members, extensions, anchors, retainers, openings, arms, biasing elements, upper ends, lower ends, devices, etc.) they modify, but are not intended to indicate any type of order, rank, importance, temporal sequence, or hierarchy. For example, ‘first X’ and ‘second X’ are intended to designate two separate X elements that are not necessarily limited by any order, rank, importance, temporal sequence, or hierarchy of the two elements, unless specifically stated to the contrary.

In the foregoing specification, a detailed description has been given with reference to specific exemplary embodiments. It will, however, be evident that various modifications and changes may be made thereto without departing from the broader spirit and scope of the disclosure as set forth in the appended claims. The specification and drawings are, accordingly, to be regarded in an illustrative sense rather than a restrictive sense. Furthermore, the foregoing use of “embodiment” and other exemplarily language does not necessarily refer to the same embodiment or the same example, but may refer to different and distinct embodiments, as well as potentially the same embodiment.

The embodiments presented herein are provided by way of example only and are intended to be non-exclusive and non-limiting. It is also important to note that the activities in the preceding flowcharts and diagrams illustrate only some of the possible activities that may be performed by a human and/or by a machine. Some of these activities may be omitted where appropriate, or these activities may be modified or changed considerably without departing from the scope of the present disclosure. In addition, the timing of these operations may be altered considerably. For example, the timing and/or sequence of certain activities may be changed relative to other activities to be performed before, after, or in parallel to the other activities, or based on any suitable combination thereof. The preceding operational flows have been offered for purposes of example and discussion. Substantial flexibility is provided by embodiments described herein in that any suitable arrangements, chronologies, configurations, and timing mechanisms may be provided without departing from the teachings of the present disclosure.

### OTHER NOTES AND EXAMPLES

The following examples pertain to embodiments in accordance with this specification. The system, apparatus, and method embodiments can include one or a combination of the following examples.

The following examples pertain to embodiments in accordance with this specification. Example A1 provides an apparatus that includes a cover and a compression mechanism coupled to the cover. The compression mechanism includes a first anchor extending through the cover, a first lever disposed in a first plane traversing the cover, and a first contact portion disposed in a second plane opposing an outer surface of the cover. The first lever and the first contact portion are in a biased relationship about a common axis, and when a rotational force is applied to the first lever, a rotational movement of the first lever causes the first contact portion to be compressed against the cover and allows the first lever to be releasably restrained by the first anchor.

Example A2 comprises the subject matter of Example A1, and the first anchor includes an upper portion with an indent sized to receive a first section of the first lever.

Example A3 comprises the subject matter of Example A2, and the indent receives the first section of the first lever when the rotational force causes the first lever to oppose the outer surface of the cover and a lateral force is applied to the first lever to move the first section into the indent.

Example A4 comprises the subject matter of any one of Examples A2-A3, and the first anchor is sized such that an upper end of the first anchor is substantially horizontally aligned with or vertically spaced below an upper surface of the first lever when the first section of the first lever is received in the indent of the first anchor.

Example A5 comprises the subject matter of any one of Examples A2-A4, and the first section is disposed between a first extension of the first lever and a second extension of the first lever.

Example A6 comprises the subject matter of Example A5, and the first section is vertically offset below the first extension and the second extension.

Example A7 comprises the subject matter of any one of Examples A2-A3, and the first section is substantially horizontally aligned along an intermediate member of the first lever.

Example A8 comprises the subject matter of any one of Examples A1-A7, and the first lever includes a first lever arm and a second lever arm.

Example A9 comprises the subject matter of Example A8, and the compression mechanism further comprises a first biasing element coupled to one end of the first lever and a second biasing element coupled to an opposite end of the first lever, and the first biasing element and the second biasing element are aligned along the common axis.

Example A10 comprises the subject matter of any one of Examples A8-A9, and the first lever arm and the second lever arm are either substantially parallel or converging.

Example A11 comprises the subject matter of any one of Examples A1-A10, and a lower end of the first anchor is coupled to a base vertically spaced below the cover.

Example A12 comprises the subject matter of Example A11, and a first contact arm of the first contact portion is vertically aligned with a first integrated circuit component positioned between the cover and the base, and a second contact arm of the first contact portion is vertically aligned with a second integrated circuit component positioned between the cover and the base.

Example A13 comprises the subject matter of any one of Examples A1-A12, and further comprises a second anchor extending through the cover, a second lever disposed in the first plane, a second contact portion disposed in the second plane, a third biasing element coupled between the first contact portion and one end of the second lever, and a fourth biasing element coupled to an opposite end of the second lever, and a second rotational movement of the second lever about the common axis biases the second contact portion against the cover and allows the second lever to be releasably restrained by the second anchor.

Example A14 comprises the subject matter of any one of Examples A1-A13, and a printed circuit board is disposed between the cover and a base.

Example A15 comprises the subject matter of A14, and the cover is a heat spreader.

Example A16 comprises the subject matter of A14, and a heat spreader is disposed between the cover and the base.

Example B1 provides a system that includes a cover, a base vertically spaced from the cover, a first anchor extending from the base to an upper end vertically spaced above the cover, and a torsional spring coupled to the cover. The torsional spring includes a first lever disposed in a first plane traversing the cover and a first contact portion disposed in a second plane opposing the cover, and the first lever and the first contact portion are in a biased relationship about a common axis. When a rotational force is applied to the first lever, the cover is compressed by the first contact portion, and the first anchor is configured to releasably restrain the first lever.

Example B2 comprises the subject matter of Example B1, and the first anchor includes an upper portion with an indent sized to receive a first section of the first lever.

Example B3 comprises the subject matter of Example B2, and the indent receives the first section of the first lever when the rotational force causes the first lever to oppose the cover and a lateral force is applied to the first lever to move the first section into the indent.

Example B4 comprises the subject matter of any one of Examples B2-B3, and the first anchor is sized such that the upper end of the first anchor is substantially horizontally aligned with or vertically spaced below an upper surface of the first lever when the first section of the first lever is received in the indent of the first anchor.

Example B5 comprises the subject matter of any one of Examples B2-B4, and the first section is disposed between a first extension of the first lever and a second extension of the first lever.

Example B6 comprises the subject matter of Example B5, and the first section is vertically offset below the first extension and the second extension.

Example B7 comprises the subject matter of any one of Examples B2-B3, and the first section is substantially horizontally aligned along an intermediate member of the first lever.

Example B8 comprises the subject matter of any one of Examples B1-B7, and the first lever includes a first lever arm and a second lever arm.

Example B9 comprises the subject matter of Example B8, and the torsional spring further comprises a first biasing element coupled to one end of the first lever and a second biasing element coupled to an opposite end of the first lever, and the first biasing element and the second biasing element are aligned along the common axis.

Example B10 comprises the subject matter of any one of Examples B8-B9, and the first lever arm and the second lever arm are either substantially parallel or converging.

Example B11 comprises the subject matter of any one of Examples B1-B10, and a first contact arm of the first contact portion is vertically aligned with a first integrated circuit component positioned between the cover and the base, and a second contact arm of the first contact portion is vertically aligned with a second integrated circuit component positioned between the cover and the base.

Example B12 comprises the subject matter of any one of Examples B1-B11, and further comprises a second anchor extending through the cover, a second lever disposed in the first plane, a second contact portion disposed in the second plane, a third biasing element coupled between the first contact portion and one end of the second lever, and a fourth biasing element coupled to an opposite end of the second lever, and a second rotational movement of the second lever about the common axis biases the second contact portion against the cover and allows the second lever to be releasably restrained by the second anchor.

Example B13 comprises the subject matter of any one of Examples B1-B13, and a printed circuit board is disposed between the cover and a base.

Example B14 comprises the subject matter of B13, and the cover is a heat spreader.

Example B15 comprises the subject matter of any one of Examples B1-B13, and a heat spreader is disposed between the cover and the base.

Example C1 provides and apparatus that includes a cover, a base, a plurality of electronic components disposed between the cover and the base, a means for compressing the cover substantially uniformly against the plurality of electronic components, a means for limiting lateral movement of the cover relative to the base, and a means for releasably restraining the means for compressing when the cover is compressed against the plurality of electronic components.

Example C2 comprises the subject matter of Example C1, and the means for compressing includes an elongated spring and a plurality of anchors extending from the base.

Example C3 comprises the subject matter of Example C2, and the elongated spring includes a plurality of levers and a plurality of contact portions biased against the plurality of levers.

Example C4 comprises the subject matter of Example C3, and the plurality of anchors is configured to releasably restrain the plurality of levers in a fixed position in which the plurality of contact portions compresses the cover against the plurality of electronic components.

Example C5 comprises the subject matter of Example C4, and a first lever of the plurality of levers includes a first section received within an indent of a first anchor of the plurality of anchors when the plurality of levers is releasably restrained in the fixed position.

Example C6 comprises the subject matter of Example C5, and the first section is disposed between a first extension and a second extension of the first lever, and the first section is vertically offset from the first extension and the second extension.

Example C7 comprises the subject matter of Example C5, and the first section is horizontally aligned along an intermediate member of the first lever.

Example C8 comprises the subject matter of any one of Examples C2-C7, and the means for limiting lateral movement of the cover relative to the base includes a plurality of through-holes in the cover.

Example C9 comprises the subject matter of Example C8, and the plurality of through-holes are sized to receive the plurality of anchors, respectively.

Example C10 comprises the subject matter of any one of Examples C1-C9, and further comprises a means for coupling the means for compressing to the cover.

Example C11 comprises the subject matter of Example C10, and the means for compressing includes a first outer arm.

Example C12 comprises the subject matter of Example C11, and the means for coupling includes an opening in the cover, and the opening is sized to receive a distal portion of the first outer arm.

Example C13 comprises the subject matter of Example C11, and the means for coupling includes an opening formed in the cover, and the opening is sized to receive a distal portion of the first outer arm.

Example M1 provides a method that includes assembling a plurality of layers of a mechanical stack assembly to a base plate, and the plurality of layers includes a cover and a first printed circuit board, coupling an elongated spring to the cover, and the elongated spring includes a plurality of levers and a plurality of contact portions, adding the cover to the mechanical stack assembly via one or more anchors, applying a rotational force to the plurality of levers to cause the plurality of contact portions to apply a compressive force to an upper surface of the cover, and applying a lateral force to the plurality of levers to releasably couple the plurality of levers to the one or more anchors, respectively.

Example M2 comprises the subject matter of Example M1, and further comprises producing the elongated spring with the plurality of levers and the plurality of contact portions.

Example M3 comprises the subject matter of any one of Examples M1-M2, and further comprises producing the cover with a first retainer and a second retainer disposed on opposite sides of the cover.

Example M4 comprises the subject matter of any one of Examples M1-M3, and further comprises forming the one or more anchors on a base plate.

Example M5 comprises the subject matter of any one of Examples M1-M3, and further comprises coupling the one or more anchors to the base plate.

Example M6 comprises the subject matter of any one of Examples M1-M5, and further comprises inserting respective sections of the plurality of levers into respective indents in the one or more anchors.

Example M7 comprises the subject matter of Example M6, and the lateral force is to be applied while the rotational force is being applied and the respective sections of the plurality of levers are substantially horizontally aligned with the respective indents of the one or more anchors.

Example M8 comprises the subject matter of any one of Examples M1-M7, and the lateral force is applied to a first lever of the plurality of levers when the first lever is substantially horizontally aligned with a first indent of a first anchor of the one or more anchors.

Example M9 comprises the subject matter of any one of Examples M1-M8, and applying the rotational force to the plurality of levers causes a first contact arm of a first contact portion of the plurality of contact portions to apply a first compressive force over a first electronic component on the first printed circuit board, and further causes a second contact arm of a second contact portion of the plurality of contact portions to apply a second compressive force over a second electronic component on the first printed circuit board.

Example M10 comprises the subject matter of any one of Examples M1-M9, and the elongated spring is a torsional sprint including a plurality of biasing elements aligned along a common axis.

Example M11 comprises the subject matter of any one of Examples M1-M10, and the plurality of layers includes a heat spreader.

1. An apparatus comprising:
a cover; and
a compression mechanism coupled to the cover, including:
a first anchor extending through the cover;
a first lever disposed in a first plane traversing the cover; and
a first contact portion disposed in a second plane opposing an outer surface of the cover, wherein the first lever and the first contact portion are in a biased relationship about a common axis, wherein when a rotational force is applied to the first lever, a rotational movement of the first lever causes the first contact portion to be compressed against the cover and allows the first lever to be releasably restrained by the first anchor.

2. The apparatus of claim 1, wherein the first anchor includes an upper portion with an indent sized to receive a first section of the first lever.

3. The apparatus of claim 2, wherein the indent receives the first section of the first lever when the rotational force causes the first lever to oppose the outer surface of the cover and a lateral force is applied to the first lever to move the first section into the indent.

4. The apparatus of claim 2, wherein the first anchor is sized such that an upper end of the first anchor is substantially horizontally aligned with or vertically spaced below an upper surface of the first lever when the first section of the first lever is received in the indent of the first anchor.

5. The apparatus of claim 2, wherein the first section is disposed between a first extension of the first lever and a second extension of the first lever.

6. The apparatus of claim 5, wherein the first section is vertically offset below the first extension and the second extension.

7. The apparatus of claim 2, wherein the first section is horizontally aligned along an intermediate member of the first lever.

8. The apparatus of claim 1, wherein the first lever includes:
a first lever arm; and
a second lever arm.

9. The apparatus of claim 8, wherein the compression mechanism further comprises:
a first biasing element coupled to one end of the first lever; and
a second biasing element coupled to an opposite end of the first lever, wherein the first biasing element and the second biasing element aligned along the common axis.

10. The apparatus of claim 8, wherein the first lever arm and the second lever arm are either substantially parallel or converging.

11. The apparatus of claim 1, wherein a lower end of the first anchor is coupled to a base vertically spaced below the cover.

12. The apparatus of claim 11, wherein a first contact arm of the first contact portion is vertically aligned with a first integrated circuit component positioned between the cover and the base, wherein a second contact arm of the first contact portion is vertically aligned with a second integrated circuit component positioned between the cover and the base.

13. The apparatus of claim 1, further comprising:
a second anchor extending through the cover;
a second lever disposed in the first plane;
a second contact portion disposed in the second plane;
a third biasing element coupled between the first contact portion and one end of the second lever; and
a fourth biasing element coupled to an opposite end of the second lever, wherein a second rotational movement of the second lever about the common axis biases the second contact portion against the cover and allows the second lever to be releasably restrained by the second anchor.

14. A system comprising:
a cover;
a base vertically spaced from the cover;
a first anchor extending from the base to an upper end vertically spaced above the cover; and
a torsional spring coupled to the cover, the torsional spring including:
a first lever disposed in a first plane traversing the cover; and
a first contact portion disposed in a second plane opposing the cover, wherein the first lever and the first contact portion are in a biased relationship about a common axis, wherein when a rotational force is applied to the first lever, the cover is compressed by the first contact portion, and wherein the first anchor is configured to releasably restrain the first lever.

15. The system of claim 14, further comprising:
a printed circuit board at least partially disposed between the cover and the base.

16. The system of claim 15, further comprising:
a heat spreader disposed between the cover and at least part of the printed circuit board.

17. The system of claim 14, wherein the cover is a heat spreader.

18. An apparatus comprising:
a cover;
a base;
a plurality of electronic components disposed between the cover and the base;
a means for compressing the cover substantially uniformly against the plurality of electronic components;
a means for limiting lateral movement of the cover relative to the base; and
a means for releasably restraining the means for compressing when the cover is compressed against the plurality of electronic components.

19. The apparatus of claim 18, wherein the apparatus further comprises:
a means for coupling the means for compressing to the cover.

20. The apparatus of claim 19, wherein the means for compressing includes a first outer arm, wherein the means for coupling includes either a retainer attached to the cover and sized to receive a distal portion of the first outer arm, or an opening in the cover sized to receive a distal portion of the first outer arm.
